(19) United States
(12) Patent Application Publication
(10) Pub. No.: US 2017/0070236 A1
(43) Pub. Date: Mar. 9, 2017

(54) AMPLIFICATION CIRCUIT AND DIGITAL-ANALOG CONVERTER

(71) Applicant: Kabushiki Kaisha Toshiba, Tokyo (JP)

(72) Inventor: Yoshinori Kawamoto, Sapporo Hokkaido (JP)

(21) Appl. No.: 15/066,918

(22) Filed: Mar. 10, 2016

Related U.S. Application Data
(60) Provisional application No. 62/215,600, filed on Sep. 8, 2015.

(51) Int. Cl. H03M 1/66; H03F 3/04

(52) U.S. Cl. CPC H03M 1/66; H03F 3/04

(57) ABSTRACT

An amplification circuit according to the present embodiment includes a first amplifier, a second amplifier, a capacitor, and an adjustment circuit. The first amplifier amplifies an input signal and outputs a first amplified signal. The second amplifier amplifies the first amplified signal input from the first amplifier through a connection line and outputs a second amplified signal. The capacitor is arranged between the connection line and an output line through which the second amplifier outputs the second amplified signal. The adjustment circuit changes a charge/discharge state of the capacitor according to a value of the input signal.

### CROSS REFERENCE TO RELATED APPLICATIONS

This application is based upon and claims the benefit of priority from the prior U.S. Provisional Patent Application No. 62/215,600, filed on Sep. 8, 2015, the entire contents of which are incorporated herein by reference.

### FIELD

The present embodiment relates to an amplification circuit and a digital-analog converter.

### BACKGROUND

Amplification circuits have been used which have a plurality of amplifiers connected therein to amplify signals. To compensate the phases of amplifiers, a capacitor is connected in such an amplification circuit. However, the transient phenomenon of the capacitor generates a settling time of output in the amplification circuit.

### BRIEF DESCRIPTION OF THE DRAWINGS

FIG. 1 is an explanatory block diagram of a configuration of an amplification circuit according to the present embodiment;

FIG. 2 is a block diagram of a configuration of an adjustment circuit;

FIGS. 3A to 3D are explanatory schematic diagrams of a settling time of an amplifier;

FIG. 4 is an explanatory schematic diagram of a configuration of a digital-analog converter;

FIG. 5 is a diagram showing a conversion table of a comparison signal output by a comparator;

FIG. 6 is an explanatory diagram of an example of a configuration of a current source and a settling completion detection circuit;

FIG. 7 is an explanatory diagram of a configuration of the settling completion detection circuit;

FIG. 8 is a table showing controls to be performed based on decoding of a comparison signal “SRBOOST[1:0]”;

FIG. 9 is an explanatory diagram of an example of a configuration of the current source and a delay generation circuit;

FIG. 10 is an explanatory diagram of a configuration of the delay generation circuit;

FIG. 11 is a table showing controls to be performed based on decoding of a comparison signal “SRBOOST[1:0]”;

FIG. 12 is a time chart of the digital-analog converter;

FIG. 13 is a time chart showing operations of the settling completion detection circuit;

FIG. 14 is a time chart showing operations of the delay generation circuit; and

FIG. 15 is a block diagram illustrating a first modification of the amplification circuit.

### DETAILED DESCRIPTION

Embodiments will now be explained with reference to the accompanying drawings. The present invention is not limited to the embodiments.

According to an embodiment, an amplification circuit of the present embodiment includes a first amplifier, a second amplifier, a capacitor, and an adjustment circuit. The first amplifier amplifies an input signal and outputs a first amplified signal. The second amplifier amplifies the first amplified signal input from the first amplifier through a connection line and outputs a second amplified signal. The capacitor is connected between the connection line and an output line through which the second amplifier outputs the second amplified signal. The adjustment circuit changes a charge/discharge state of the capacitor according to a value of the input signal.

The amplification circuit according to the present embodiment is configured to shorten a settling time by changing the charge/discharge state of the capacitor according to the value of the input signal. Hereinafter, detailed descriptions of the amplification circuit will be given.

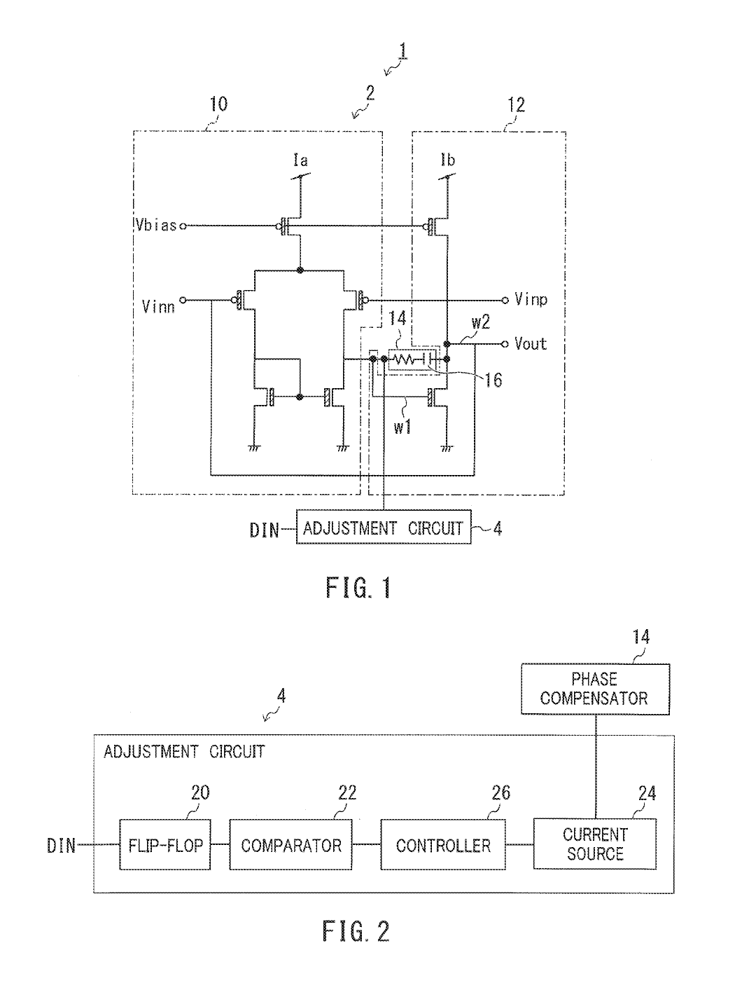

The configuration of an amplification circuit 1 according to the present embodiment will be described based on FIG. 1. FIG. 1 is an explanatory block diagram of the configuration of the amplification circuit 1 according to a first embodiment. As illustrated in FIG. 1, the amplification circuit 1 according to the present embodiment includes a circuit 2 and an adjustment circuit 4. The circuit 2 amplifies an input signal in two stages. That is, the circuit 2 includes a first amplifier 10, a second amplifier 12, and a phase compensator 14.

The first amplifier 10 amplifies an input signal and outputs a first amplified signal. The first amplifier 10 amplifies a difference (Vinp−Vinn) between values of signals input to a Vinp terminal and a Vinn terminal and outputs the amplified signals as the first amplified signal.

The second amplifier 12 amplifies the first amplified signal input from the first amplifier 10 through a connection line W1 and outputs a second amplified signal. That is, the second amplifier 12 outputs the second amplified signal through an output line W2.

The phase compensator 14 includes a capacitor 16. That is, the capacitor 16 is arranged between the connection line W1 and the output line W2 through which the second amplifier 12 outputs the second amplified signal.

The adjustment circuit 4 changes the charge/discharge state of the capacitor 16 according to the value of an input signal “DIN”. That is, the adjustment circuit 4 changes the change amount of the charge amount accumulated in the capacitor 16 per unit time, according to the change amount of the value of the input signal “DIN”. The “DIN” is a digital signal. A one-data-rate input signal is expressed as “DIN(n)”, where “n” is an integral and represents a generation order of the concerned input signal, that is, a generation order of a clock.

The configuration of the adjustment circuit 4 will be described based on FIG. 2. FIG. 2 is a block diagram of the configuration of the adjustment circuit 4. As illustrated in FIG. 2, the adjustment circuit 4 includes a flip-flop 20, a comparator 22, a current source 24, and a controller 26.

The flip-flop 20 holds a one-data-rate input signal “DIN(n−1)” for one clock, that is, for a time corresponding to one data rate and outputs the input signal “DIN(n−1)”. That is, the flip-flop 20 outputs the input signal “DIN(n−1)” that is an input signal of a previous data rate at a timing of receiving a one-data-rate input signal “DIN(n)”.

The comparator 22 outputs a comparison signal that is based on the difference value between the one-data-rate input signal “DIN(n)” and the previous one-data-rate input signal “DIN(n−1)” output by the flip-flop 20. The current source 24 supplies current for charging/discharging to the capacitor 16. That is, the current source 24 is used to change the charge/discharge state of the capacitor 16.

The controller 26 controls the current source 24 that sends current to the capacitor 16 according to the comparison signal output by the comparator 22. That is, the controller 26 changes the change amount of a charge amount accumulated in the capacitor 16 per unit time according to the change amount of the value of the input signal.

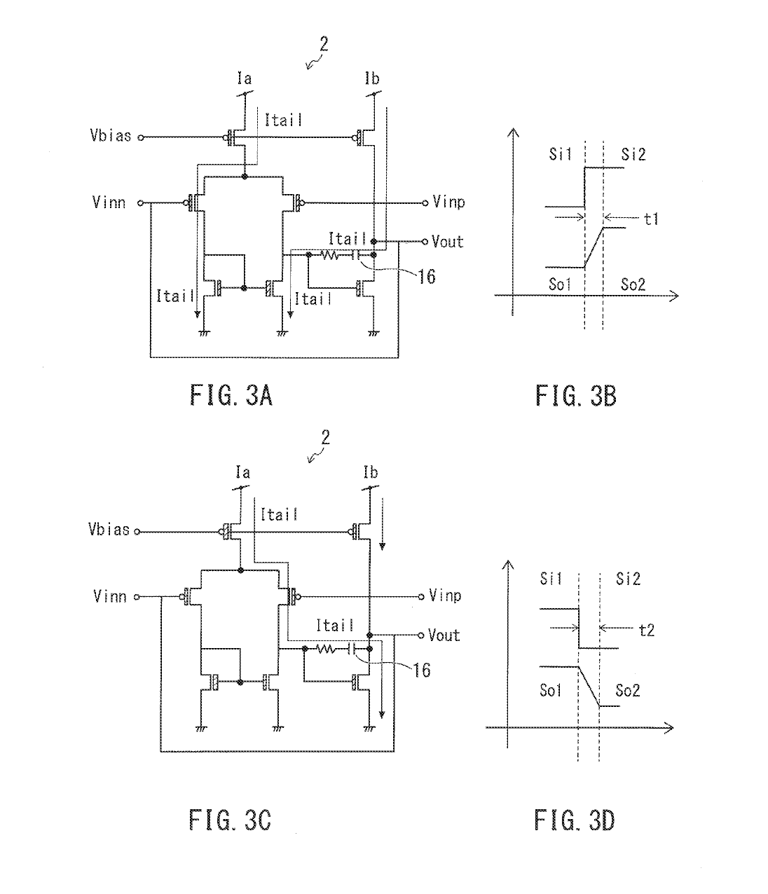

A settling time in an amplifier will be described based on FIGS. 3A to 3D. FIGS. 3A and 3C are each the circuit diagram of an amplifier. FIGS. 3B and 3D are graphs each showing input signals and output signals. A situation where no current is supplied from the adjustment circuit 4 to the capacitor 16 will be described.

In FIGS. 3B and 3D, the abscissa represents a time “t” and the ordinate represents a voltage value “V” of a signal. In each graph, “Si1” denotes an input signal corresponding to an input signal “DIN(n−1)” that is an input signal of a previous data rate. “Si2” denotes an input signal corresponding to a one-data-rate input signal “DIN(n)”. “So1” denotes a signal that is obtained by amplifying the input signal “Si1” in the amplification circuit 1 and is output by the amplification circuit 1. “So2” denotes a signal that is obtained by amplifying the input signal “Si2” in the amplification circuit 1 and is output by the amplification circuit 1.

As illustrated in FIGS. 3A and 3B, when “Si2” is larger than “Si1”, a current “Itail” flows into the first amplifier 10 through the capacitor 16. In this case, in changing of the So1 output to the So2 output, it takes a time “t1” to converge the output value of the amplification circuit 1 to “So2”. The time “t1” is a settling time and is caused by the transient phenomenon of the capacitor 16 that is generated according to the change of the current “Itail”. As the absolute value of the difference between “So1” and “So2” becomes larger, the settling time “t1” becomes longer. That is, as the change amount of the value of the input signal becomes larger, the settling time “t1” becomes longer.

On the other hand, as illustrated in FIGS. 3C and 3D, when “Si2” is smaller than “Si1”, the current “Itail” flows from the first amplifier 10 to the outside through the capacitor 16. In this way, the direction of the current “Itail” flowing through the capacitor 16 when “Si2” is larger than “Si1” is opposite to that when “Si2” is smaller than “Si1”. In this case, in changing of the So1 output to the So2 output, it takes a time “t2” to converge the output value of the amplification circuit 1 to “So2”. The time “t2” is a settling time. Therefore, a time taken to converge the transient phenomenon of the capacitor 16 needs to be shortened in order to shorten a settling time. As an example of methods of shortening the settling time, a method of increasing the current “Itail” constantly has been known. However, constant increase in the current “Itail” results in increase in power consumption.

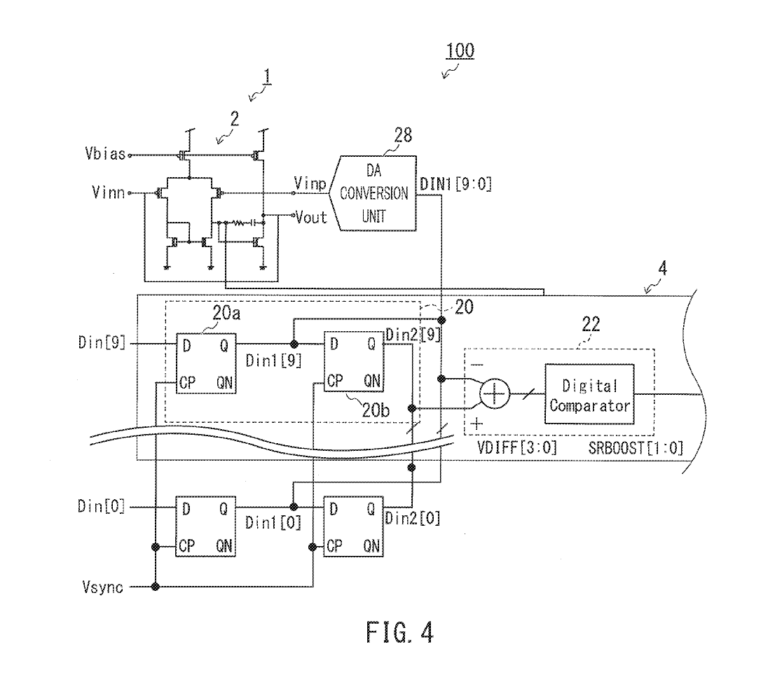

The configuration of a digital-analog converter 100 will be described based on FIG. 4. FIG. 4 is an explanatory schematic diagram of the configuration of the digital-analog converter 100.

As illustrated in FIG. 4, the digital-analog converter 100 includes the amplification circuit 1 and a DA conversion unit 28. The DA conversion unit 28 converts an input signal from a digital signal to an analog signal and outputs the analog signal to the amplification circuit 1. In the adjustment circuit 4 in FIG. 4, only the flip-flop 20 and the comparator 20 are illustrated.

The flip-flop 20 includes a flip-flop 20a and a flip-flop 20b. The flip-flop 20a receives “DIN[9]”, holds “DIN[9]” for one clock, and outputs the signal as “DIN1[9]”. The flip-flop 20b receives “DIN1[9]”, holds “DIN1[9]” for one clock and outputs the signal as a “DIN2[9]”.

In this way, the flip-flop 20 in this case outputs “DIN2[9]”. That is, “DIN2[9]” corresponds to an input signal of one data rate previous to “DIN1[9]”. “DIN2[9]” and “DIN1[9]” are input to the comparator 22. On the other hand, “DIN1[9]” is input to the DA conversion unit 28 and converted from a digital signal to an analog signal. “Vinn” in this case is assumed to be a fixed value, for example, “0”. That is, in this case, the first amplifier 10 can be substantially regarded as a single-input amplification circuit.

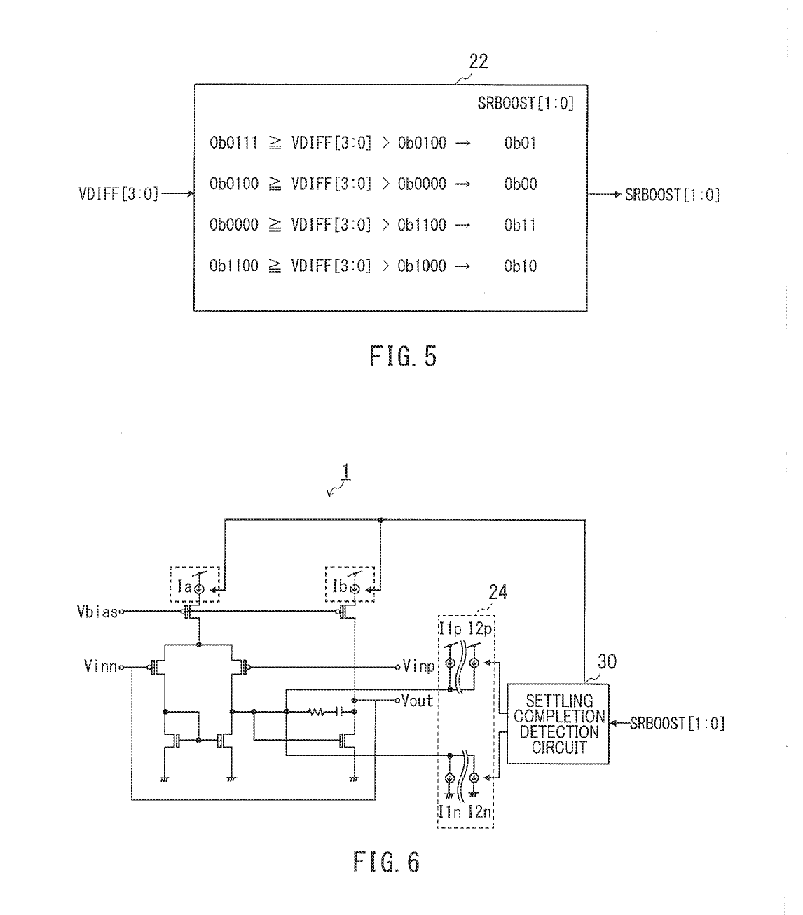

An example of a comparison signal output by the comparator 22 will be described based on FIG. 5 with reference to FIG. 4. FIG. 5 is a diagram showing a conversion table of a comparison signal output by the comparator 22. In FIG. 5, “VDIFF[3:0]” indicates a difference value between a value of a one-data-rate input signal and a value of a one-data-rate input signal of the previous data rate. That is, in FIG. 5, the difference between “DIN1[9]” illustrated in FIG. 4 and “DIN2[9]” that is an input signal of a data rate previous to “DIN1[9]” is “VDIFF[3:0]”.

As illustrated in FIG. 5 again, when “VDIFF[3:0]” is larger than 4 and not more than 7, the comparator 22 outputs “0b01” as a comparison signal “SRBOOST[1:0]”. Similarly, when “VDIFF[3:0]” is larger than 0 and not more than 4, the comparator 22 outputs “0b00” as the comparison signal “SRBOOST[1:0]”. When “VDIFF[3:0]” is larger than −4 and not more than 0, the comparator 22 outputs “0b11” as the comparison signal “SRBOOST[1:0]”. When “VDIFF[3:0]” is larger than −7 and not more than −4, the comparator 22 outputs “0b10” as the comparison signal “SRBOOST[1:0]”. In this way, the comparator 22 outputs the comparison signal “SRBOOST[1:0]” corresponding to the difference value between a value of a one-data-rate input signal and a value of a previous one-data-rate input signal.

FIG. 6 is an explanatory diagram of an example of the configuration of the current source 24 and the controller 26. A settling completion detection circuit 30 is a part of the controller 26. As illustrated in FIG. 6, in the current source 24, a plurality of current sources I1p and I2p and a plurality of current sources I1n and I2n are connected in parallel. The direction of current supplied to the end of the capacitor 16 from the current sources I1p and I2p is different from that from the current sources I1n and I2n.

The settling completion detection circuit 30 selects any of the current sources I1p, I2p, I1n, and I2n based on the comparison signal “SRBOOST[1:0]” output by the comparator 22 and controls the selected current sources to supply current to the capacitor 16. That is, in this case, as the number of selected current sources increases, the current supply increases.

The settling completion detection circuit 30 may control the amount of current supplied from the current sources Ia and Ib, which supply the current “Itail” in the amplification circuit 1. That is, the settling completion detection circuit 30 may change the supply amount of the current “Itail” per unit time according to the comparison signal “SRBOOST[1:0]”. In this way, the supply amount of the current “Itail” per unit time may be increased according to the change of the input signal.

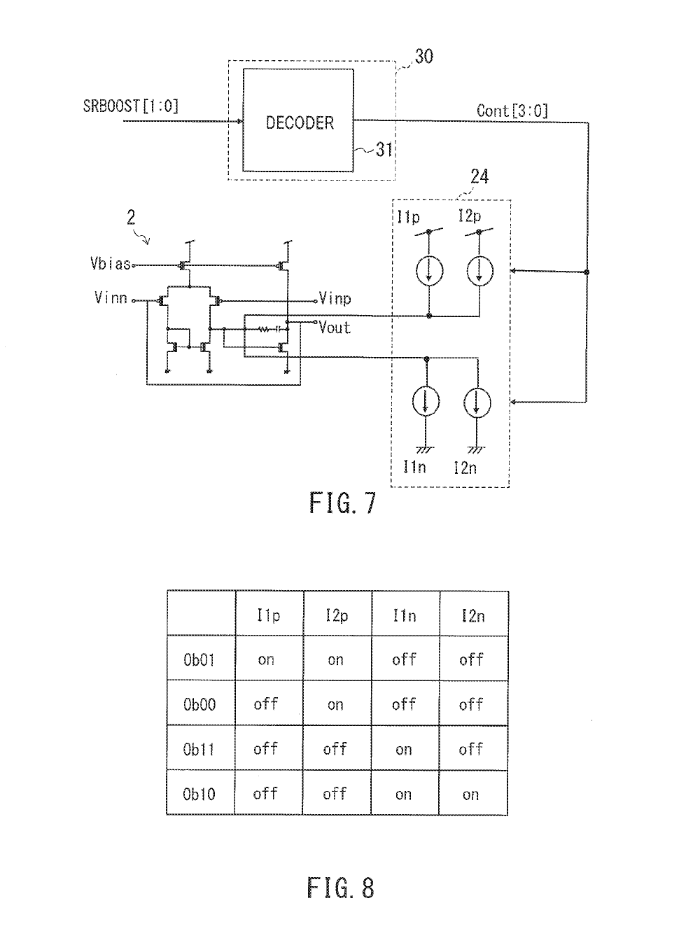

FIG. 7 is a more specific configuration diagram of the settling completion detection circuit 30. As illustrated in FIG. 7, the settling completion detection circuit 30 has a decoder 31. That is, the decoder 31 decodes the comparison signal “SRBOOST[1:0]” and outputs a control signal “Cont[3:0]” to the current source 24.

An example of control based on the comparison signal “SRBOOST[1:0]” will be described based on FIG. 8 with reference to FIG. 5. FIG. 8 is a table showing controls to be performed based on decoding of the comparison signal “SRBOOST[1:0]”. In the table, “on” indicates that a corresponding current source is selected and “off” indicates that a corresponding current source is not selected.

As illustrated in FIG. 8, when the comparison signal “SRBOOST[1:0]” is “0b01”, the current sources I1p and I2p are selected. Similarly, when the comparison signal “SRBOOST[1:0]” is “0b00”, the current source I2p is selected. Similarly, when the comparison signal “SRBOOST[1:0]” is “0b11”, the current source I1n is selected. Similarly, when the comparison signal “SRBOOST[1:0]” is “0b10”, the current sources I1n and I2n are selected.

With reference to FIG. 5 again, when the difference value “VDIFF[3:0]” is larger than 4 and not more than 7, the current sources I1p and I2p supply current. When the difference value “VDIFF[3:0]” is larger than 0 and not more than 4, the current source I2p supplies current. Consequently, as the difference value “VDIFF[3:0]”, that is, the change amount of the value of the input signal becomes larger, the change amount of the charge amount accumulated in the capacitor 16 per unit time becomes larger. That is, as the change amount of the value of the input signal becomes larger, the charge/discharge amount of the charge amount accumulated in the capacitor 16 per unit time increases. Consequently, as the change amount of the value of the input signal becomes larger, a time taken to converge the transient phenomenon of the capacitor 16 is shortened more. As the change amount of the value of the input signal becomes smaller, current supplied from the current source 24 decreases more thereby suppressing the power consumption.

On the other hand, when the difference value “VDIFF[3:0]” is larger than −7 and not more than −4, the current source I1n and I2n supply current. When the difference value “VDIFF[3:0]” is larger than −4 and not more than 0, the current source I1n supplies current. In this way, the amount and direction of current supplied to the capacitor 16 are changed according to the increase/decrease in value of the input signal. Consequently, the charge/discharge speed of the capacitor 16 is adjusted according to increase/decrease in value of the input signal. Accordingly, the settling time can be shortened even more and the power consumption can be reduced even more.

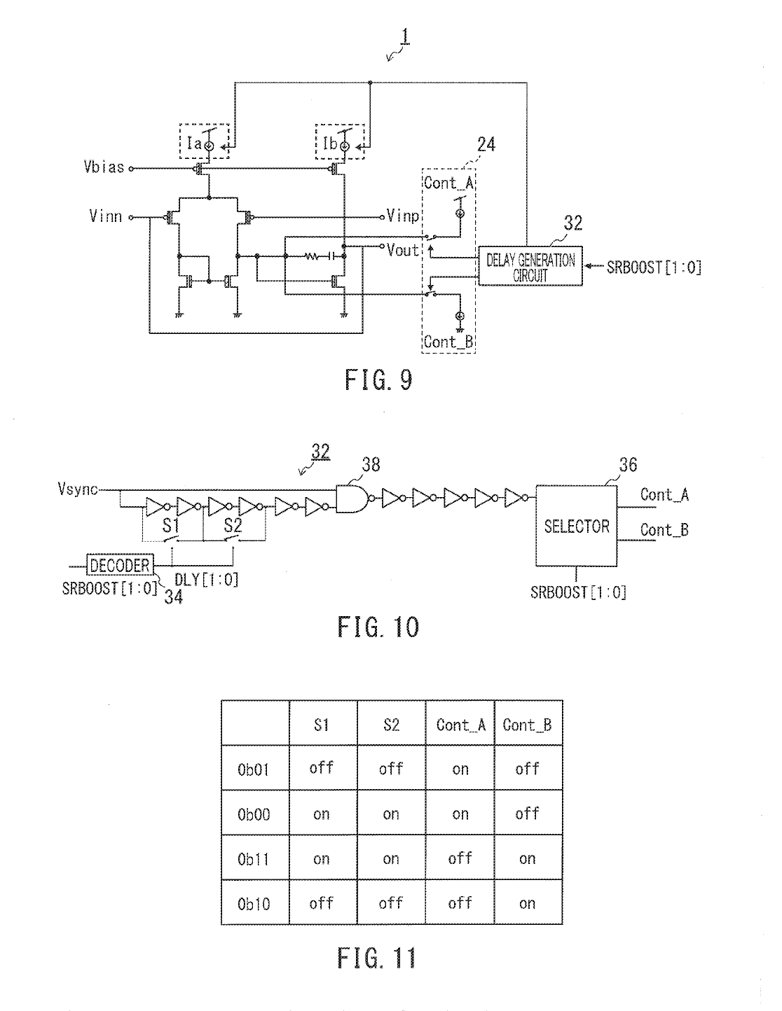

An example of the configuration of the current source 24 and the controller 26 will be described based on FIG. 9. A delay generation circuit 32 is a part of the controller 26. As illustrated in FIG. 9, the current source 24 includes current sources “Cont_A” and “Cont_B”. The current sources “Cont_A” and “Cont_B” supply current to the capacitor 16. The delay generation circuit 32 performs control to change the time for supplying current to the capacitor 16 and the direction of the current based on the comparison signal “SRBOOST[1:0]” output by the comparator 22. That is, the delay generation circuit 32 selects a current source among from the current sources “Cont_A” and “Cont_B” according to the change amount of the value of the input signal and controls the time for supplying current from the current source 24 to the capacitor 16 and the direction of the current. As in FIG. 6, the delay generation circuit 32 may control the current amounts from the current sources Ia and Ib, which supply the current “Itail”.

The configuration of the delay generation circuit 32 will be described based on FIG. 10. FIG. 10 is an explanatory diagram of the configuration of the delay generation circuit 32. As illustrated in FIG. 10, the delay generation circuit 32 is a circuit for controlling a time for supplying current and includes a decoder 34, a selector 36, and a delay circuit 38.

The decoder 34 decodes a comparison signal “SRBOOST[1:0]” and outputs a control signal “DLY[1:0]”. Switching of switching elements S1 and S2 is controlled according to the control signal “DLY[1:0]”.

The selector 36 selects a current source according to the comparison signal “SRBOOST[1:0]”. That is, the selector 36 selects the current source “Con_A” or the current source “Cont_B”.

The delay circuit 38 delays a stop signal to be output to the selector 36 according to the signal from the decoder 34. At the time of input of the stop signal to the selector 36, the current is stopped.

When the switching elements S1 and S2 are off, the delay time is the longest and the time for supplying current from the current source 24 is the longest. Subsequently, when the switching element S1 is turned on, that is, the connection of the switching element S1 is established, the delay time is shortened by two logic elements. When the switching elements S1 and S2 are turned on, that is, the connections of the switching elements S1 and S2 are established, the delay time is shortened by four logic elements. Consequently, when the switching elements S1 and S2 are off, the time for supplying current to the capacitor 16 is the longest, and when the switching elements S1 and S2 are on, the time for supplying current to the capacitor 16 is the shortest. That is, as the time for supplying current becomes longer, the charge amount charged/discharged to/from the capacitor 16 for a predetermined time is increased.

Consequently, the charge/discharge speed of the capacitor 16 is adjusted according to increase/decrease in value of the input signal. Accordingly, the settling time can be shortened even more and the power consumption can be reduced even more. That is, when the change in value of the input signal is small, power supply is reduced thereby reducing the power consumption even more.

An example of controlling the delay generation circuit 32 according to the comparison signal “SRBOOST[1:0]” will be described based on FIG. 11 with reference to FIG. 5. FIG. 11 is a table showing controls to be performed based on decoding of a comparison signal “SRBOOST[1:0]”.

As illustrated in FIG. 11, when the comparison signal “SRBOOST[1:0]” is “0b01”, the switching elements S1 and S2 are off and the selector 36 selects the current source Cont_A. Similarly, when the comparison signal “SRBOOST[1:0]” is “0b00”, the switching elements S1 and S2 are on and the selector 36 selects the current source Cont_A. Similarly, when the comparison signal “SRBOOST[1:0]” is “0b11”, the switching elements S1 and S2 are off and the selector 36 selects the current source Cont_B. Similarly, when the comparison signal “SRBOOST[1:0]” is “0b10”, the switching elements S1 and S2 are on and the selector 36 selects the current source Cont_B.

With reference to FIG. 5 again, when the difference value “VDIFF[3:0]” is larger than 4 and not more than 7, the switching elements S1 and S2 are off and the time for supplying current to the capacitor 16 is the longest. When the difference value “VDIFF[3:0]” is larger than 0 and not more than 4, the switching elements S1 and S2 are on and the time for supplying current to the capacitor 16 is shorter than that when the difference value “VDIFF[3:0]” is larger than 4 and not more than 7. Consequently, as the difference value “VDIFF[3:0]”, that is, the change amount of the value of the input signal becomes larger, the current amount supplied to the capacitor 16 increases. Accordingly, as the change amount of the value of the input signal becomes larger, the time taken to converge the transient phenomenon of the capacitor 16 is shortened.

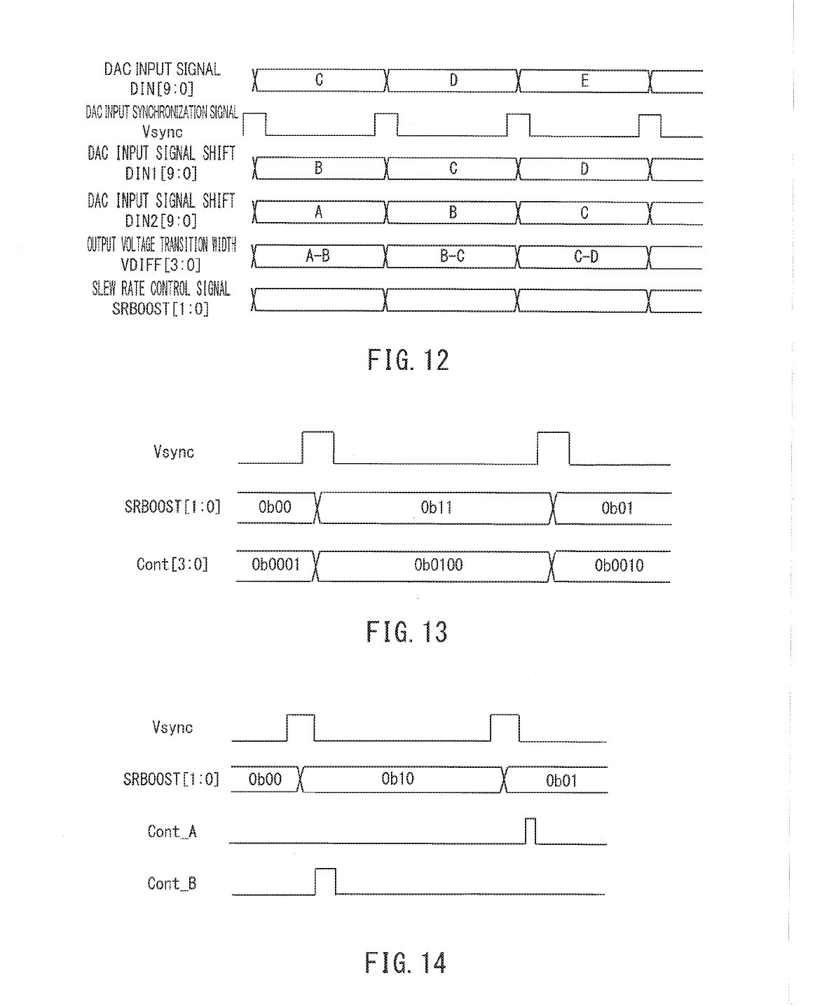

The descriptions of the entire configuration of the digital-analog converter 100 according to the present embodiment have been given above. Next, descriptions of operations of the digital-analog converter 100 will be given based on FIG. 12 with reference to FIG. 4.

FIG. 12 is a time chart of the digital-analog converter 100. In FIG. 12, the abscissa represents a time. “DCA input signal DIN[9:0]” denotes an input signal to the flip-flop 20a in the first stage. “DCA input synchronization signal Vsync” denotes a clock control signal. “DCA input signal shift DIN1[9:0]” denotes an output signal from the flip-flop 20a in the first stage as well as an input signal to a DA converter. “DCA input signal shift DIN2[9:0]” denotes an output signal from the flip-flop 20b in the second stage.

“Output voltage transition width VDIFF[3:0]” denotes a difference signal of the comparator 22, that is, a difference value between “DIN1[9:0]” and “DIN2[9:0]”. “Slew rate control signal SRBOOST[1:0]” denotes a comparison signal of the comparator 22. Consequently, the slew rate control signal “SRBOOST[1:0]” corresponding to an input signal to the D/A converter is based on the difference between the input signal “DIN1[9:0]” to the D/A converter and the input signal “DIN2[9:0]” to the D/A converter of a previous clock. That is, current supply to the capacitor 16 is controlled based on the difference value between the input signal “DIN1[9:0]” to the D/A converter and the input signal “DIN2[9:0]” to the D/A converter of the previous clock.

Operations of the settling completion detection circuit 30 will be described based on FIG. 13 with reference to FIGS. 5, 7, and 8. FIG. 13 is a time chart showing operations of the settling completion detection circuit 30. In FIG. 13, the abscissa represents a time. “Vsync” denotes a clock control signal. “Slew rate control signal SRBOOST[1:0]” denotes the comparison signal in FIG. 5. That is, when “SRBOOST[1:0]” is “0b00”, the current source I2p is selected as shown in FIG. 8. “SRBOOST[1:0]” is decoded to a control signal “Cont[3:0]” by the decoder 31. That is, in this case, “0b0001” is output as “Cont[3:0]” from the settling completion detection circuit 30.

In the subsequent clock, since “SRBOOST[1:0]” is “0b11”, the current sources I1n and I2n are selected as shown in FIG. 8. In this case, a signal “0b0100” is output as “Cont[3:0]” from the settling completion detection circuit 30 to the current source. In this way, the current source 24 is controlled according to “SRBOOST[1:0]”.

Operations of the delay generation circuit 32 will be described based on FIG. 14 with reference to FIGS. 9 to 11. FIG. 14 is a time chart showing operations of the delay generation circuit 32. In FIG. 14, the abscissa represents a time. “Vsync” denotes a clock control signal. “Slew rate control signal SRBOOST[1:0]” denotes the comparison signal in FIG. 5. That is, since “SRBOOST[1:0]” is “0b10”, the switching elements S1 and S2 are off as shown in FIG. 10 and the current source Cont_B is selected. In the subsequent clock, since “SRBOOST[1:0]” is “0b01”, the switching elements S1 and S2 are off as shown in FIG. 10 and the current source Cont_A is selected. In this way, the current source 24 is controlled according to “SRBOOST[1:0]”.

### (Modification)

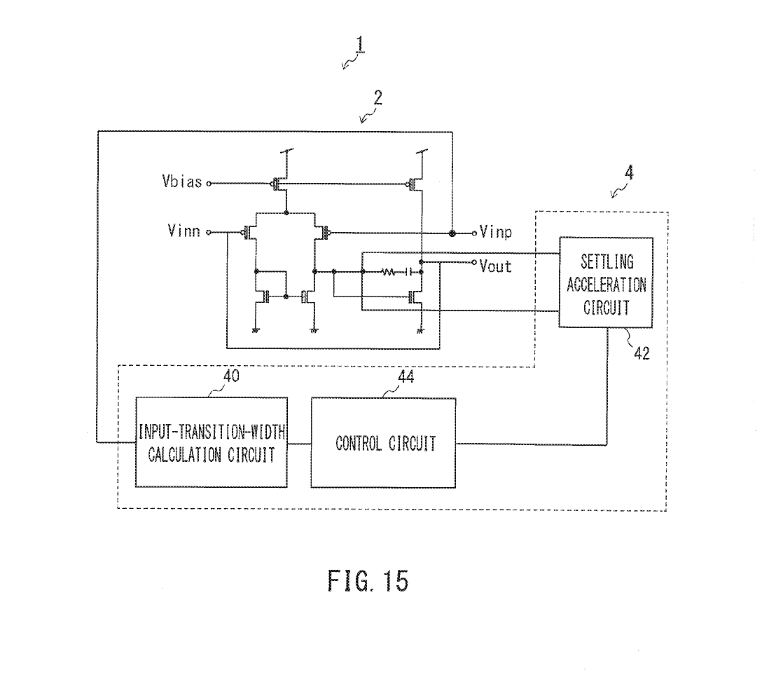

A modification of the amplification circuit 1 will be described based on FIG. 15. FIG. 15 is a block diagram illustrating a modification of the amplification circuit 1. The amplification circuit 1 in FIG. 15 differs from that in FIG. 1 in that a signal having been input to the VinP terminal is input to the adjustment circuit 4, as illustrated in FIG. 15. Differences from the amplification circuit 1 in FIG. 1 will be described below.

The adjustment circuit 4 includes an input-transition-width calculation circuit 40, a settling acceleration circuit 42, and a control circuit 44.

The input-transition-width calculation circuit 40 calculates a difference value of an input signal from the VinP per unit time. That is, the input-transition-width calculation circuit 40 can calculate a value indicating a settling time even when input signals continuously vary.

The settling acceleration circuit 42 is a circuit including a current source. That is, an amount of current sent from the settling acceleration circuit 42 to the capacitor 16 and a time for sending the current are controlled according to the value indicating a settling time. The control circuit 44 controls the settling acceleration circuit 42 according to the value calculated by the input-transition-width calculation circuit 40.

As described above, the input-transition-width calculation circuit 40 calculates the difference value of input signals per unit time. Accordingly, when input signals continuously vary, the settling time can be shortened. In the present embodiment, the input-transition-width calculation circuit 40 and the settling acceleration circuit 42 correspond to a calculator and a setting circuit respectively.

As described above, according to the amplification circuit 1 of the present embodiment, the adjustment circuit 4 changes the charge/discharge state of the capacitor 16 according to the change value of an input signal. Therefore, the settling time can be shortened even more and the power consumption can be reduced even more.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and theft equivalents are intended to cover such forms or modifications as would fall within the scope and spirit of the inventions.

1. An amplification circuit comprising:
a first amplifier configured to amplify an input signal and output a first amplified signal;
a second amplifier configured to amplify the first amplified signal input from the first amplifier through a connection line and output a second amplified signal;
a capacitor arranged between the connection line and an output line through which the second amplifier outputs the second amplified signal; and
an adjustment circuit configured to change a charge/discharge state of the capacitor according to a value of the input signal.

2. The amplification circuit according to claim 1, wherein
the adjustment circuit changes a change amount of a charge amount accumulated in the capacitor per unit time according to a change amount of the value of the input signal.

3. The amplification circuit according to claim 2, wherein
the adjustment circuit increases the change amount of the charge amount accumulated in the capacitor per unit time, as the change amount of the value of the input signal becomes larger.

4. The amplification circuit according to claim 1, wherein
the adjustment circuit changes an amount of current sent from a current source to the capacitor according to a change amount of the value of the input signal.

5. The amplification circuit according to claim 1, wherein
the adjustment circuit changes a direction of current sent to the capacitor according to increase/decrease in value of the input signal.

6. The amplification circuit according to claim 1, wherein
the adjustment circuit changes the charge/discharge state of the capacitor by selecting a current source for supplying current from among a plurality of current sources connected to the capacitor in parallel.

7. The amplification circuit according to claim 1, wherein
the adjustment circuit changes a time for sending current from a current source to the capacitor according to a change amount of the value of the input signal.

8. An digital-analog converter comprising:
a digital-analog conversion circuit configured to convert an input signal from a digital signal to an analog signal;
a first amplifier configured to amplify the input signal having been converted to the analog signal and output a first amplified signal;
a second amplifier configured to amplify the first amplified signal input from the first amplifier through a connection line and output a second amplified signal;
a capacitor arranged between the connection line and an output line through which the second amplifier outputs the second amplified signal; and
an adjustment circuit configured to change a charge/discharge state of the capacitor according to a value of the input signal.

9. The digital-analog converter according to claim 8, wherein the adjustment circuit changes the charge/discharge state of the capacitor according to a difference value between a one-data-rate input signal value and an input signal value of one data rate previous to the one-data-rate input signal.

10. The digital-analog converter according to claim 8, wherein
the adjustment circuit includes:
a flip-flop configured to receive a one-data-rate input signal;
a comparator configured to output a comparison signal based on the one-data-rate input signal and an input signal of a previous data rate output by the flip-flop; and
a controller configured to control a current source sending current to the capacitor according to the comparison signal.

11. The digital-analog converter according to claim 10, wherein
the controller changes a direction of current sent to the capacitor according to a sign of the difference value.

12. The digital-analog converter according to claim 10, wherein
the controller performs control to operate a current source for supplying current from among a plurality of current sources connected to the capacitor in parallel according to the difference value.

13. The digital-analog converter according to claim 10, wherein
the controller controls a time for sending current from the current source supplying charge to the capacitor according to the difference value.

14. An amplification circuit comprising:
a digital-analog conversion circuit configured to convert an input signal from a digital signal to an analog signal;
a first amplifier configured to amplify the input signal having been converted to the analog signal and output a first amplified signal;
a second amplifier configured to amplify the first amplified signal input from the first amplifier through a connection line and output a second amplified signal;
a capacitor arranged between the connection line and an output line through which the second amplifier outputs the second amplified signal;
a calculator configured to calculate a value indicating a settling time taken to converge an output value output by the second amplifier to a predetermined value;
a setting circuit configured to shorten the settling time by sending current to the capacitor; and
a control circuit configured to control the setting circuit according to the value.

15. The amplification circuit according to claim 14, wherein
the settling time is obtained based on a difference value of input signals per unit time.
